(19) United States
(12) Patent Application Publication
(10) Pub. No.: US 2012/0168211 A1
(43) Pub. Date: Jul. 5, 2012

(54) SUBSTRATE ASSEMBLY CONTAINING CONDUCTIVE FILM AND FABRICATION METHOD THEREOF

(75) Inventors: Chun-An LU, Xinzhuang City (TW); Hong-Ching LIN, Kaohsiung City (TW); Shih-Ming CHEN, Hsinchu City (TW); Wen-Pin TING, Kaohsiung City (TW)

(73) Assignee: INDUSTRIAL TECHNOLOGY RESEARCH INSTITUTE, Hsinchu (TW)

(21) Appl. No.: 13/221,414

(22) Filed: Aug. 30, 2011

(30) Foreign Application Priority Data
Dec. 30, 2010 (TW) 99146826

(51) Int. Cl. H05K 1/03; C08F 2/48; C08F 2/46; B82Y 99/00

(52) U.S. Cl. 174/257; 427/487; 427/493; 257/40; 977/788

(57) ABSTRACT

A substrate assembly containing a conductive film and a fabrication method thereof are provided. The substrate assembly includes a polymer substrate, a surface treatment layer formed on the polymer substrate and a conductive film formed on the surface treatment layer, wherein the conductive film is formed by sintering a metal conductive ink and the surface treatment layer is formed from a composite material of an auxiliary filler and a polymer. The auxiliary filler in the surface treatment layer can deliver energy into the metal conductive ink for sintering the conductive metal ink.

### CROSS REFERENCE TO RELATED APPLICATIONS

This application claims priority of Taiwan Patent Application No. 99146826, filed on Dec. 30, 2010, the entirety of which is incorporated by reference herein.

### BACKGROUND OF THE INVENTION

1. Field of the Invention

The invention relates to a substrate assembly, and more particularly to a substrate assembly having a conductive film and a fabrication method thereof.

2. Description of the Related Art

Currently, flexible electronic technologies are performed by directly printing conductive wires on flexible substrates to reduce manufacturing cost. In order to achieve conductive wires with high reliability, the adhesion between the conductive wires and the flexible substrate needs to be enhanced.

One conventional method for increasing the adhesion between the conductive wires and the flexible substrate is a conductive ink modifying method, which is used to increase the adhesion of the conductive ink. Another conventional method is a substrate modifying method, which is used to increase the adhesion of the substrate. The conductive ink modifying method is for example the method disclosed in U.S. Pub. No. 2007/0048514, in which a mixture of a porous conductive material and a porous polymer material is used to increase the adhesion between a conductive layer and a polymer substrate. In addition, U.S. Pub. No. 2004/0144958 discloses using a polymer material with a low glass transition temperature (Tg) as an adhesion accelerating agent which is added into a conductive ink to increase the adhesion between the conductive ink and a substrate.

The substrate modifying method is for example the method disclosed in U.S. Pub. No. 2009/0104474, in which a metal alkoxide layer is used to treat a surface of a substrate by a cracking process, a microwave treatment or a hydrolysis process to form an oxide adhesive layer for increasing the adhesion of the surface of the substrate. In addition, U.S. Pat. No. 5,190,795 discloses using a coupling agent to coat an inorganic oxide layer on a surface of a substrate, and then performing a heating process to make the inorganic oxide layer adhere on the surface of the substrate, such that the adhesion between the substrate and the inorganic oxide layer is enhanced.

The conductive ink modifying methods are performed by adding a polymer material into the conductive ink, such that the adhesion between a conductive film formed by sintering the conductive ink and the substrate is enhanced through the polymer material. However, the conductivity of the conductive film is reduced by the polymer material in the conductive ink. The substrate modifying methods are performed by forming an adhesive layer such as an oxide layer on the surface of the substrate to increase the adhesion of the surface of the substrate. However, the adhesive layer on the surface of the substrate does not have other additive functions except for increasing the adhesion of the surface of the substrate.

### BRIEF SUMMARY OF THE INVENTION

The invention provides a substrate assembly containing a conductive film. The substrate assembly comprises a polymer substrate, a surface treatment layer disposed on the polymer substrate and a conductive film disposed on the surface treatment layer, wherein the surface treatment layer is formed from a composite material of an auxiliary filler and a polymer, and the conductive film is formed by sintering a metal conductive ink. The auxiliary filler in the surface treatment layer has an energy delivering ability for delivering an energy to the metal conductive ink for sintering the metal conductive ink.

The invention further provides a method for fabricating a substrate assembly. The method comprises providing a polymer substrate. A mixture of an auxiliary filler and a polymer is coated on the polymer substrate and then the mixture of the auxiliary filler and the polymer is solidified to form a surface treatment layer. A metal conductive ink is coated on the surface treatment layer. Then, a first energy source and an second energy source are applied to the polymer substrate, the surface treatment layer and the metal conductive ink for sintering the metal conductive ink to form a conductive film, wherein the auxiliary filler in the surface treatment layer has an energy delivering ability for delivering the energies of the first energy source and the second energy source to the metal conductive ink for sintering the metal conductive ink.

A detailed description is given in the following embodiments with reference to the accompanying drawings.

### BRIEF DESCRIPTION OF THE DRAWINGS

The invention can be more fully understood by reading the subsequent detailed description and Examples with reference to the accompanying drawings, wherein:

FIG. 1 shows a schematic cross section of a substrate assembly having a conductive film according to an embodiment of the invention; and

FIGS. 2A-2D show schematic cross sections of various stages of a method for fabricating a substrate assembly having a conductive film according to an embodiment of the invention.

### DETAILED DESCRIPTION OF THE INVENTION

The following description is of the best-contemplated mode of carrying out the invention. The description is provided for illustrating the general principles of the invention and is not meant to be limiting. The scope of the invention is best determined by reference to the appended claims.

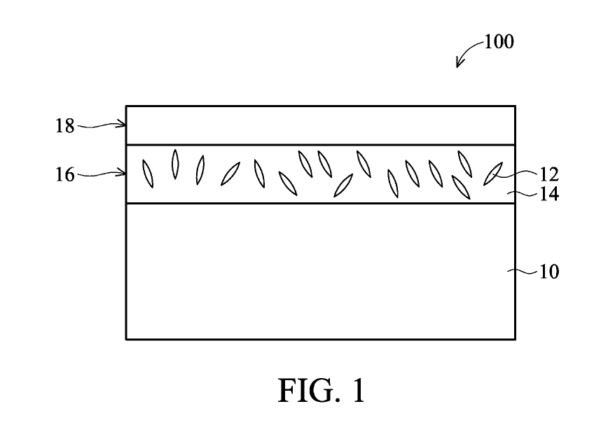

Referring to FIG. 1, a cross section of a substrate assembly 100 having a conductive film according to an embodiment of the invention is shown. The substrate assembly 100 includes a polymer substrate 10 and a surface treatment layer 16 disposed on the polymer substrate 10. Furthermore, a conductive film 18 is disposed on the surface treatment layer 16.

The polymer substrate 10 may be a flexible substrate formed from a thermoplastic polymer, a thermosetting polymer or composite materials thereof, for example polyethylene terephthalate (PET), polyacrylic (U-Polymer) or polycarbonate (PC). The polymer substrate 10 has an insulating resistance greater than 10¹⁴ Ω/sq, preferably between 10¹⁴ Ω/sq and 10¹⁶ Ω/sq, and more preferably between 10¹⁵ Ω/sq and 10¹⁶ Ω/sq. The polymer substrate 10 has a glass transition temperature (T_{g}) greater than 80° C., preferably between 80° C. and 160° C., and more preferably between 100° C. and 150° C.

The surface treatment layer 16 is formed from a composite material of an auxiliary filler 12 and a polymer 14. One function of the surface treatment layer 16 is to increase the adhesion between the conductive film 18 and the polymer substrate 10 through the polymer 14 therein. Another function of the surface treatment layer 16 is to improve sintering of a metal conductive ink through the auxiliary filler 12 therein to form the conductive film 18. The surface treatment layer 16 has an insulating sheet resistivity greater than 10¹⁶ Ω/sq and an adhesion force between the surface treatment layer 16 and the polymer substrate 10 and an adhesion force between the surface treatment layer 16 and the conductive film 18 greater than 4B.

In the embodiments of the invention, a weight ratio of the auxiliary filler 12 in the surface treatment layer 16 is less than 5 wt %, preferably between 0.01 wt % and 5 wt %, and more preferably between 0.05 wt % and 3 wt %. The auxiliary filler 12 may be nanometer scale tubes, nanometer scale spheres, carbon containing materials, clays or combinations thereof. The nanometer scale tube is for example, a nanometer scale carbon tube, a nanometer scale metal tube or a nanometer scale non-metal tube. The nanometer scale sphere is for example, a nanometer scale carbon sphere, a nanometer scale metal sphere or a nanometer scale non-metal sphere. The carbon containing material is for example, graphite or graphite oxide. The clay is for example, a clay composite of oxides of elements in Group IA, Group IIA and Group IVA of the periodic table. The nanometer scale carbon tube may be a single-walled nanometer scale carbon tube or a multi-walled nanometer scale carbon tube. The materials of the nanometer scale metal tube and the nanometer scale metal sphere may be at least one metal selected from the group consisting of titanium, manganese, zinc, copper, silver, gold, tin, iron, nickel, cobalt, indium and aluminum, or the other suitable materials. The materials of the nanometer scale non-metal tube and the nanometer scale non-metal sphere may be titanium oxide, manganese oxide, zinc oxide, silver oxide, iron oxide, tin oxide, nickel oxide, indium oxide or the other metal oxides.

The polymer 14 in the surface treatment layer 16 may be a thermoplastic polymer, a thermosetting polymer or composite materials thereof. The polymer 14 has a glass transition temperature (T_{g}) between 75° C. and 200° C. The thermoplastic polymer is for example, polyethylene, polypropylene, polyoxymethylene, polycarbonate, polyvinyl chloride, polyvinyl alcohol, polymethyl methacrylate, polystyrene, polyimide, polyethylene naphthalate or poly(ethylene succidate). The thermosetting polymer is for example, epoxy resin, acrylic resin, unsaturated polyester, phenolic resin or silicon polymers. Moreover, in addition to the auxiliary filler 12 and the polymer 14, the surface treatment layer 16 may further include other organic or inorganic additives to help fabricating processes of the surface treatment layer 16 or to improve properties of the surface treatment layer 16.

The conductive film 18 is formed by sintering a metal conductive ink. In the embodiments of the invention, the composition of the metal conductive ink comprises a metallo-organic compound and a solvent. In the metal conductive ink, the weight ratio of the metallo-organic compound is less than 60 wt % and preferably between 25 wt % and 50 wt %. The metallo-organic compound is a precursor for forming the conductive film 18, represented by (RCOO)_{y}M^{(y)}, wherein R is a straight-chain or a branched-chain CₙH₂₊₁, n is an integral of 5-20, M is metal, which may be at least one metal selected from the group consisting of copper, silver, gold, aluminum, titanium, nickel, tin, iron, platinum and palladium, or the other suitable materials, and y is a valence of the metal. The metallo-organic compound can be reduced through a metallo-organic decomposition (MOD) reaction to form nanometer scale metal particles. Then, a pure metal conductive film 18 with high conductivity is formed through a low-temperature melting property of the nanometer scale metal particles. Thus, the metal conductive film 18 with high conductivity is formed by a process with a low temperature. A temperature range of the process for forming the conductive film 18 through the reduction of the metallo-organic compound depends on the temperature of reducing the metallo-organic compound to metal particles.

The auxiliary filler 12 in the surface treatment layer 16 has an energy delivering ability for delivering an energy. Through the energy delivering ability of the auxiliary filler 12 for delivering an energy such as heat, light or energy waves, the energy can be effectively delivered to the metal conductive ink to change a reduction energy level of the metallo-organic compound and decrease a reduction temperature of the metallo-organic compound in the metal conductive ink. Moreover, the auxiliary filler 12 can deliver the energy to the nanometer scale metal particles which formed from the metallo-organic compound to increase the surrounding temperature of the nanometer scale metal particles to the melting point of the nanometer scale metal particles for effectively decreasing a temperature when sintering the metal conductive ink. Accordingly, the pure metal conductive film 18 is formed when a temperature of a background environment is low and the sintering time is short, and the auxiliary filler 12 in the surface treatment layer 16 can be applied to the polymer substrate 10 with a low softening temperature.

In addition to the metallo-organic compound and the solvent, a metal powder may be added to the metal conductive ink. The metal powder is for example, a sub-micrometer or a nanometer scale metal powder with a sphere-shape or a sheet-shape. The size of the metal powder is smaller than 500 nm. The material of the metal powder is selected from the group consisting of copper, silver, gold, aluminum, titanium, nickel, tin, iron, platinum and palladium. The solvent in the metal conductive ink may be a polar or a non-polar solvent, for example xylene, toluene, terpenol or combinations thereof. Moreover, other organic or inorganic additives to help fabricating processes of the conductive film 18 or to improve properties of the conductive film 18 may be added to the metal conductive ink.

Also, the metal conductive ink may directly consist of a plurality of metal particles and a solvent. The auxiliary filler 12 in the surface treatment layer 16 can deliver an energy to the metal particles to increase the surrounding temperature of the metal particles to the melting point of the metal particles and effectively decrease a sintering temperature of the metal conductive ink, which helps for sintering the metal conductive ink to form the conductive film 18.

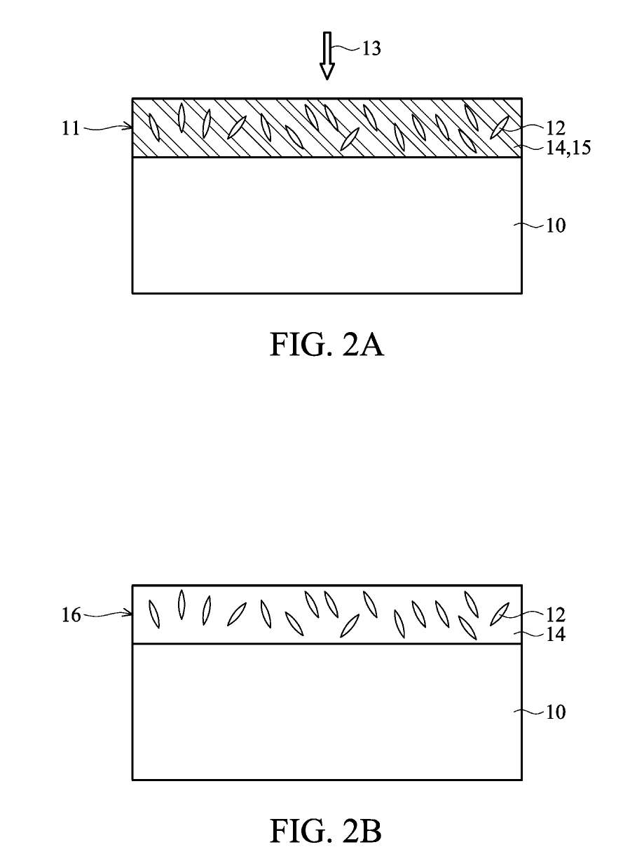

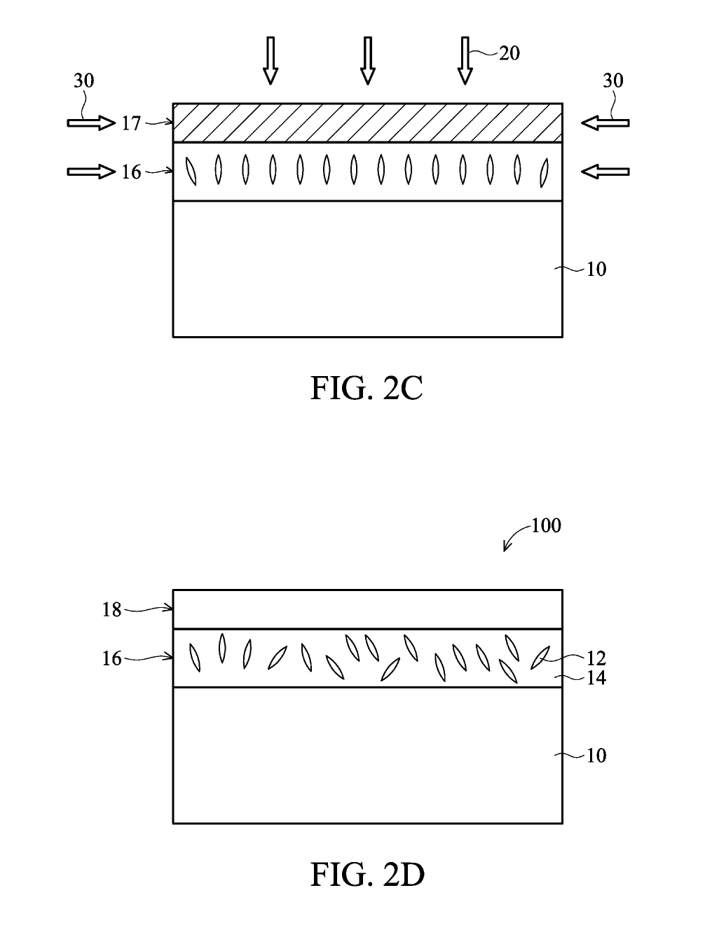

Referring to FIGS. 2A-2D, cross sections of various stages of a method for fabricating a substrate assembly 100 having a conductive film according to an embodiment of the invention are shown. Referring to FIG. 2A, first, the polymer substrate 10 is provided. Next, a mixture 11 of the auxiliary filler 12, the polymer 14 and the solvent 15 is coated on the polymer substrate 10 by a wet coating method, such as a spin coating or a screen printing process. Then, the mixture 11 is solidified by a solidification process 13, such as a UV light illuminating or a heating process to remove the solvent 15 therein to form the surface treatment layer 16, as shown in FIG. 2B.

Referring to FIG. 2C, a metal conductive ink 17 is coated on the surface treatment layer 16 by a wet coating method, such as a spin coating or a screen printing process. Then, a first energy source 30 and an auxiliary second energy source 20 are applied to the polymer substrate 10, the surface treatment layer 16 and the metal conductive ink 17 for sintering the metal conductive ink 17 to form the conductive film 18, as shown in FIG. 2D. In an embodiment, the conductive film 18 has a resistivity of less than 10×10⁻³ Ω·cm.

The first energy source 30 and the second energy source 20 can be a form of heat, light, energy waves or laser, which are applied to the assembly of the polymer substrate 10, the surface treatment layer 16 and the metal conductive ink 17 through various directions, which are not limited to the directions as shown in FIG. 2C. In the first and second energy sources, the heat-typed energy source may be a form of conduction heat, convection heat or radiation heat. The light-typed energy source may be a form of an ultraviolet light, a near-infrared light, a middle-infrared light or a far-infrared light. The energy wave-type energy source may be a microwave with a wavelength of 300 MHz-300 GHz. The laser-typed energy source may be a gaseous laser, a solid-state laser or a liquid laser. The gaseous laser may be an excimer laser, argon ion laser, carbon dioxide (CO₂) laser or hydrogen-fluoride compound (HF) laser. The solid-state laser may be a diode laser, wherein the wavelength of the diode laser includes 266 nm, 355 nm, 532 nm or 1064 nm. The form of the first energy source 30 is different from that of the second energy source 20. In an embodiment, the first energy source is an energy provided from a baking system, which has a temperature range between 90° C. and 150° C., preferably between 100° C. and 130° C., and more preferably about 120° C. The second energy source is a far-infrared light which assists in sintering the metal conductive ink 17.

Because the auxiliary filler 12 in the surface treatment layer 16 has an energy delivering ability to assist in delivering the energies of the first energy source and the second energy source to the metal conductive ink 17 for sintering the metal conductive ink 17, the conductive film 18 is formed when a temperature of a background environment is low, and the sintering time is short. Thus, the polymer substrate 10 with a low softening temperature does not deform.

The materials, the fabrication methods and the characters of the substrate assembly 100 of the invention are described in detail by several Examples and Comparative Examples as below:

### Examples 1-4

A mixture was 0.5 wt % multi-walled nanometer scale carbon tubes mixed with 99.5 wt % polymer system which an acrylic resin of 55 wt % was mixed with methylethyl ketone (MEK) of 45 wt %. Then, the mixture was coated on a substrate made of polyethylene terephthalate (PET). The substrate has a thickness of 150 μm, a glass transition temperature of 80° C. and an insulating resistance of 1.82×10¹³ Ω/sq. The mixture was solidified by UV light to form a surface treatment layer having an insulating sheet resistance greater than 10¹⁴ Ω/sq.

Next, an organic acid silver (C₇H₁₅COOAg) compound of 50 wt % was dissolved in and uniformly mixed with a solvent of xylene of 50 wt % to form a metal conductive ink. Then, the metal conductive ink was coated on the surface treatment layer by a spin coating process to fabricate conductive films of the Examples 1-4. The fabrication conditions of the conductive films of the Examples 1-4 were implemented by a heat process consisting of a background temperature of 150° C. with or without an auxiliary energy of far-infrared light to sinter the metal conductive inks.

Then, the conductive films of the Examples 1-4 were measured by a cross-cut tape test of ASTM D3330, a four-point probe method and a hardness test of ASTM D3363 to obtain the adhesion forces, the sheet resistances and the hardnesses as shown in Table 1.

### Comparative Examples 1-4

A mixture was an acrylic resin of 55 wt % mixed with methyl ethyl ketone (MEK) of 45 wt %. Then, the mixture was coated on a PET substrate. The PET substrate has a thickness of 150 μm, a glass transition temperature of 80° C. and an insulating resistance of 1.82×10¹³ Ω/sq. The mixture was solidified by UV light to form a surface treatment layer having an insulating sheet resistance greater than 9.55×10¹⁰ Ω/sq.

Next, an organic acid silver (C₇H₁₅COOAg) compound of 39.8 wt % was dissolved in and uniformly mixed with a solvent of xylene of 59.7 wt % to form a metal conductive ink. Then, the metal conductive ink was coated on the surface treatment layer by a spin coating process to fabricate conductive films of the Comparative Examples 1-4. The fabrication conditions of the conductive films of the Comparative Examples 1-4 were implemented by a heat process consisting of a background temperature of 150° C. with or without an auxiliary energy of far-infrared light to sinter the metal conductive inks.

Then, the conductive films of the Comparative Examples 1-4 were measured by a cross-cut tape test of ASTM D3330, a four-point probe method and a hardness test of ASTM D3363 to obtain the adhesion forces, the sheet resistances and the hardnesses as shown in Table 1.

Table 1 displays the compositions of the metal conductive inks, the fabrication conditions, the adhesion forces, the sheet resistances and the hardnesses of the conductive films of Examples 1-4 and Comparative Examples 1-4

| | time of | | | background | | | |
|---|---|---|---|---|---|---|---|
| | far- | composition of | | temperature | | | |
| | infrared | metal | | 150° C. | | adhesion | hardness |
| | light | conductive ink | | sheet | time of | test | test |
| | radiation | C₇H₁₅COOAg | xylene | resistance | sintering | ASTM | ASTM |
| | (minutes) | (wt %) | (wt %) | (Ω/sq) | (minutes) | D3330 | D3360 |
| Comparative | 5 | 50 | 50 | 0.33 | 5 | 3B | 3B |
| Example 1 | | | | | | | |
| Comparative | 10 | 50 | 50 | 0.15 | 10 | 3B | 6B |
| Example 2 | | | | | | | |
| Comparative | — | 50 | 50 | 0.39 | 5 | 1B | 6B |
| Example 3 | | | | | | | |
| Comparative | — | 50 | 50 | 0.16 | 10 | 0B | 5B |
| Example 4 | | | | | | | |
| Example 1 | 5 | 50 | 50 | 2.63M | 5 | 1B | 6B |
| Example 2 | 10 | 50 | 50 | 0.14 | 10 | 1B | 6B |
| Example 3 | — | 50 | 50 | 128K | 5 | 0B | 6B |
| Example 4 | — | 50 | 50 | 0.64 | 10 | 0B | 6B |

As shown in the results of Table 1, compared with the surface treatment layers of Comparative Examples 1-4 without adding the multi-walled nanometer scale carbon tubes, the conductive film of Example 2 coated on the surface treatment layer containing the multi-walled nanometer scale carbon tubes therein and formed by an auxiliary irradiated process by a far-infrared light for 10 minutes has a preferred sheet resistance. Moreover, compared with the fabrication conditions with no auxiliary energy of far-infrared light of Comparative Examples 3-4, the conductive films of Examples 1-2 formed from coating the metal conductive inks on the surface treatment layers containing the multi-walled nanometer scale carbon tubes therein and formed by an auxiliary irradiated process by a far-infrared light have stable hardnesses and adhesion forces.

### Examples 5-8

A mixture was 1 wt % multi-walled nanometer scale carbon tubes mixed with 99 wt % polymer system which polyacrylic (U-Polymer) of 55 wt % was mixed with a solvent of N-methyl-2-pyrrolidone (NMP) of 45 wt %. Then, the mixture was coated on a U-Polymer substrate with a thickness of 150 μm, a glass transition temperature of 160° C. and an insulating resistance greater than 10¹⁴ Ω/sq. The mixture was solidified by UV light to form a surface treatment layer having an insulating sheet resistance of 9.95×10¹⁰ Ω/sq.

Next, an organic acid silver (C₇H₁₅COOAg) compound of 50 wt % was dissolved in and uniformly mixed with a solvent of xylene of 50 wt % to form a metal conductive ink. Then, the metal conductive ink was coated on the surface treatment layer by a spin coating process to fabricate conductive films of the Examples 5-8. The fabrication conditions of the conductive films of the Examples 5-8 were implemented by a heat process consisting of a background temperature of 150° C. with or without an auxiliary energy of far-infrared light to sinter the metal conductive inks.

Then, the conductive films of the Examples 5-8 were measured by a cross-cut tape test of ASTM D3330, a four-point probe method and a hardness test of ASTM D3363 to obtain the adhesion forces, the sheet resistances and the hardnesses as shown in Table 2.

### Comparative Examples 5-8

A mixture was polyacrylic (U-Polymer) of 55 wt % mixed with a solvent of N-methyl-2-pyrrolidone (NMP) of 45 wt %. Then, the mixture was coated on a U-Polymer substrate with a thickness of 150 μm, a glass transition temperature of 160° C. and an insulating resistance greater than 10¹⁴ Ω/sq. The mixture was solidified by UV light to form a surface treatment layer having an insulating sheet resistance greater than 10¹⁴ Ω/sq.

Next, an organic acid silver (C₇H₁₅COOAg) compound of 50 wt % was dissolved in and uniformly mixed with a solvent of xylene of 50 wt % to form a metal conductive ink. Then, the metal conductive ink was coated on the surface treatment layer by a spin coating process to fabricate conductive films of the Comparative Examples 5-8. The fabrication conditions of the conductive films of the Comparative Examples 5-8 were implemented by a heat process consisting of a background temperature of 150° C. with or without an auxiliary energy of far-infrared light to sinter the metal conductive inks.

Then, the conductive films of the Comparative Examples 5-8 were measured by a cross-cut tape test of ASTM D3330, a four-point probe method and a hardness test of ASTM D3363 to obtain the adhesion forces, the sheet resistances and the hardnesses as shown in Table 2.

Table 2 displays the compositions of the metal conductive inks, the fabrication conditions, the adhesion forces, the sheet resistances and the hardnesses of the conductive films of Examples 5-8 and Comparative Examples 5-8

| | time of | | | background | | | |
|---|---|---|---|---|---|---|---|
| | far- | composition of | | temperature | | | |
| | infrared | metal | | 150° C. | | adhesion | hardness |
| | light | conductive ink | | sheet | time of | test | test |
| | radiation | C₇H₁₅COOAg | xylene | resistance | sintering | ASTM | ASTM |
| | (minutes) | (wt %) | (wt %) | (Ω/sq) | (minutes) | D3330 | D3360 |
| Comparative | 5 | 50 | 50 | 18.19M | 5 | 0B | 6B |
| Example 5 | | | | | | | |
| Comparative | 10 | 50 | 50 | 0.29 | 10 | 4B | 6B |
| Example 6 | | | | | | | |
| Comparative | — | 50 | 50 | X | 5 | — | — |
| Example 7 | | | | | | | |
| Comparative | — | 50 | 50 | 126.4K | 10 | 3B | 6B |
| Example 8 | | | | | | | |
| Example 5 | 5 | 50 | 50 | 1.63M | 5 | 0B | 6B |
| Example 6 | 10 | 50 | 50 | 0.21 | 10 | 5B | 2B |
| Example 7 | — | 50 | 50 | 24.9M | 5 | — | — |
| Example 8 | — | 50 | 50 | 1.9K | 10 | — | 6B |

X: non-conductive

As shown in the results of Table 2, compared with fabrication conditions with no auxiliary energy of far-infrared light of Comparative Examples 7-8, the conductive film of Example 6 coated on the U-Polymer surface treatment layer containing the multi-walled nanometer scale carbon tubes therein and formed by an auxiliary irradiated process by a far-infrared light for 10 minutes has a preferred hardness of 2B and a preferred adhesion force of 5B.

### Examples 9-12

A mixture was 1 wt % multi-walled nanometer scale carbon tubes mixed with 99 wt % polymer system which polyvinyl alcohol of 5 wt % was mixed with ethanol of 95 wt %. Then, the mixture was coated on a polycarbonate (PC) substrate with a thickness of 150 μm, a glass transition temperature of 125° C. and an insulating resistance of 1.42×10¹⁴ Ω/sq. The mixture was solidified by baking at 150° C. to form a surface treatment layer having an insulating sheet resistance of 1.07×10¹³ Ω/sq.

Next, an organic acid silver (C₇H₁₅COOAg) compound of 50 wt % was dissolved in and uniformly mixed with a solvent of xylene of 50 wt % to form a metal conductive ink. Then, the metal conductive ink was coated on the surface treatment layer by a spin coating process to fabricate conductive films of the Examples 9-12. The fabrication conditions of the conductive films of the Examples 9-12 were implemented by a heat process consisting of a background temperature of 150° C. with or without an auxiliary energy of far-infrared light to sinter the metal conductive inks.

Then, the conductive films of the Examples 9-12 were measured by a cross-cut tape test of ASTM D3330, a four-point probe method and a hardness test of ASTM D3363 to obtain the adhesion forces, the sheet resistances and the hardnesses as shown in Table 3.

### Comparative Examples 9-12

A mixture was polyvinyl alcohol (PVA) of 5 wt % mixed with a solvent of ethanol of 95 wt %. Then, the mixture was coated on a PC substrate with a thickness of 150 μm, a glass transition temperature of 125° C. and an insulating resistance of 1.42×10¹⁴ Ω/sq. The mixture was solidified by baking at 150° C. to form a surface treatment layer having an insulating sheet resistance of 1.02×10¹³ Ω/sq.

Next, an organic acid silver (C₇H₁₅COOAg) compound of 50 wt % was dissolved in and uniformly mixed with a solvent of xylene of 50 wt % to form a metal conductive ink. Then, the metal conductive ink was coated on the surface treatment layer by a spin coating process to fabricate conductive films of the Comparative Examples 9-12. The fabrication conditions of the conductive films of the Comparative Examples 9-12 were implemented by a heat process consisting of a background temperature of 150° C. with or without an auxiliary energy of far-infrared light to sinter the metal conductive inks.

Then, the conductive films of the Comparative Examples 9-12 were measured by a cross-cut tape test of ASTM D3330, a four-point probe method and a hardness test of ASTM D3363 to obtain the adhesion forces, the sheet resistances and the hardnesses as shown in Table 3.

Table 3 displays the compositions of the metal conductive inks, the fabrication conditions, the adhesion forces, the sheet resistances and the hardnesses of the conductive films of Examples 9-12 and Comparative Examples 9-12

| | time of | | | background | | | |
|---|---|---|---|---|---|---|---|
| | far- | composition of | | temperature | | | |
| | infrared | metal | | 150° C. | | adhesion | hardness |
| | light | conductive ink | | sheet | time of | test | test |
| | radiation | C₇H₁₅COOAg | xylene | resistance | sintering | ASTM | ASTM |
| | (minutes) | (wt %) | (wt %) | (Ω/sq) | (minutes) | D3330 | D3360 |
| Comparative | 5 | 50 | 50 | 1.36 | 5 | 2B | 6B |
| Example 9 | | | | | | | |
| Comparative | 10 | 50 | 50 | 0.23 | 10 | 4B | 5B |
| Example 10 | | | | | | | |
| Comparative | — | 50 | 50 | 12M | 5 | 0B | 6B |
| Example 11 | | | | | | | |
| Comparative | — | 50 | 50 | 0.21 | 10 | 2B | 6B |
| Example 12 | | | | | | | |
| Example 9 | 5 | 50 | 50 | 1.34 | 5 | 4B | 6B |
| Example 10 | 10 | 50 | 50 | 0.35 | 10 | 4B | 6B |
| Example 11 | — | 50 | 50 | 10.1M | 5 | 0B | 6B |
| Example 12 | — | 50 | 50 | 2.49 | 10 | 3B | 6B |

As shown in the results of Table 3, compared with fabrication conditions with no auxiliary energy of far-infrared light of Comparative Examples 11-12, the conductive film of Example 10 coated on the PVA surface treatment layer containing the multi-walled nanometer scale carbon tubes therein and formed by an auxiliary irradiated process by a far-infrared light for 10 minutes has a high and stable adhesion force of 4B and a low sheet resistance of 0.35 Ω/sq.

### Examples 13-16

A mixture was 1 wt % multi-walled nanometer scale carbon tubes mixed with 99 wt % polymer system which polyvinyl alcohol of 5 wt % was mixed with ethanol of 95 wt %. Then, the mixture was coated on a polycarbonate (PC) substrate with a thickness of 150 μm, a glass transition temperature of 125° C. and an insulating resistance of 1.42×10¹⁴ Ω/sq. The mixture was solidified by baking at 150° C. to form a surface treatment layer having an insulating sheet resistance of 5.34×10¹² Ω/sq.

Next, an organic acid silver (C₇H₁₅COOAg) compound of 50 wt % was dissolved in and uniformly mixed with a solvent of xylene of 50 wt % to form a metal conductive ink. Then, the metal conductive ink was coated on the surface treatment layer by a spin coating process to fabricate conductive films of the Examples 13-16. The fabrication conditions of the conductive films of the Examples 13-16 were implemented by a heat process consisting of a background temperature of 150° C. with or without an auxiliary energy of far-infrared light to sinter the metal conductive inks.

Then, the conductive films of the Examples 13-16 were measured by a cross-cut tape test of ASTM D3330, a four-point probe method and a hardness test of ASTM D3363 to obtain the adhesion forces, the sheet resistances and the hardnesses as shown in Table 4.

Table 4 displays the compositions of the metal conductive inks, the fabrication conditions, the adhesion forces, the sheet resistances and the hardnesses of the conductive films of Examples 13-16

| | time of | | | background | | | |
|---|---|---|---|---|---|---|---|
| | far- | composition of | | temperature | | | |
| | infrared | metal | | 150° C. | | adhesion | hardness |
| | light | conductive ink | | sheet | time of | test | test |
| | radiation | C₇H₁₅COOAg | xylene | resistance | sintering | ASTM | ASTM |
| | (minutes) | (wt %) | (wt %) | (Ω/sq) | (minutes) | D3330 | D3360 |
| Example 13 | 5 | 50 | 50 | 0.42 | 5 | 0B | 6B |
| Example 14 | 10 | 50 | 50 | 0.14 | 10 | 0B | 5B |
| Example 15 | — | 50 | 50 | 0.69 | 5 | 0B | 6B |
| Example 16 | — | 50 | 50 | 0.21 | 10 | 0B | 4B |

As shown in the results of Table 4, compared with fabrication conditions with no auxiliary energy of far-infrared light of Examples 15-16, the conductive films of Examples 13-14 coated on the PVA surface treatment layer containing clay therein and formed by an auxiliary irradiated process by a far-infrared light of 5 and 10 minutes, respectively, have low and stable sheet resistances.

### Examples 17-20

A mixture was 1 wt % multi-walled nanometer scale carbon tubes mixed with 99 wt % polymer system which polyvinyl alcohol of 5 wt % was mixed with ethanol of 95 wt %. Then, the mixture was coated on a polycarbonate (PC) substrate with a thickness of 150 μm, a glass transition temperature of 125° C. and an insulating resistance of 1.42×10¹⁴ Ω/sq. The mixture was solidified by baking at 150° C. to form a surface treatment layer having an insulating sheet resistance of 1.49×10¹³ Ω/sq.

Next, an organic acid silver (C₇H₁₅COOAg) compound of 50 wt % was dissolved in and uniformly mixed with a solvent of xylene of 50 wt % to form a metal conductive ink. Then, the metal conductive ink was coated on the surface treatment layer by a spin coating process to fabricate conductive films of the Examples 17-20. The fabrication conditions of the conductive films of the Examples 17-20 were implemented by a heat process consisting of a background temperature of 150° C. with or without an auxiliary energy of far-infrared light to sinter the metal conductive inks.

Then, the conductive films of the Examples 17-20 were measured by a cross-cut tape test of ASTM D3330, a four-point probe method and a hardness test of ASTM D3363 to obtain the adhesion forces, the sheet resistances and the hardnesses as shown in Table 5.

Table 5 displays the compositions of the metal conductive inks, the fabrication conditions, the adhesion forces, the sheet resistances and the hardnesses of the conductive films of Examples 17-20

| | time of | | | background | | | |
|---|---|---|---|---|---|---|---|
| | far- | composition of | | temperature | | | |
| | infrared | metal | | 150° C. | | adhesion | hardness |
| | light | conductive ink | | sheet | time of | test | test |
| | radiation | C₇H₁₅COOAg | xylene | resistance | sintering | ASTM | ASTM |
| | (minutes) | (wt %) | (wt %) | (Ω/sq) | (minutes) | D3330 | D3360 |
| Example 17 | 5 | 50 | 50 | 4.8 | 5 | 4B | 6B |
| Example 18 | 10 | 50 | 50 | 0.23 | 10 | 5B | 6B |
| Example 19 | — | 50 | 50 | 15.85M | 5 | 1B | 6B |
| Example 20 | — | 50 | 50 | 0.25 | 10 | 5B | 6B |

As shown in the results of Table 5, compared with fabrication conditions with no auxiliary energy of far-infrared light and a short sintering time of Example 19, the conductive film of Example 17 coated on the PVA surface treatment layer containing the nanometer scale carbon spheres therein and formed by an auxiliary irradiated process by a far-infrared light of 5 minutes has a high adhesion force of 4B and a low sheet resistance of 4.8 Ω/sq.

### Examples 21-24

A mixture was 1 wt % multi-walled nanometer scale carbon tubes mixed with 99 wt % polymer system which polyvinyl alcohol of 5 wt % was mixed with ethanol of 95 wt %. Then, the mixture was coated on a polycarbonate (PC) substrate with a thickness of 150 μm, a glass transition temperature of 125° C. and an insulating resistance of 1.42×10¹⁴ Ω/sq. The mixture was solidified by baking at 150° C. to form a surface treatment layer having an insulating sheet resistance of 1.07×10¹³ Ω/sq.

Next, an organic acid silver (C₇H₁₅COOAg) compound of 50 wt % was dissolved in and uniformly mixed with a solvent of xylene of 50 wt % to form a metal conductive ink. Then, a sphere-shaped silver powder with a particle size of 400 nm was added in the metal conductive ink by 10 wt % of the metal conductive ink to form a final conductive ink. The final conductive ink was coated on the surface treatment layer by a spin coating process to fabricate conductive films of the Examples 21-24. The fabrication conditions of the conductive films of the Examples 21-24 were implemented by a heat process consisting of a background temperature of 150° C. with or without an auxiliary energy of far-infrared light to sinter the final conductive inks.

Then, the conductive films of the Examples 21-24 were measured by a cross-cut tape test of ASTM D3330, a four-point probe method and a hardness test of ASTM D3363 to obtain the adhesion forces, the sheet resistances and the hardnesses as shown in Table 6.

Table 6 displays the compositions of the metal conductive inks, the fabrication conditions, the adhesion forces, the sheet resistances and the hardnesses of the conductive films of Examples 21-24

| | time of | | | | background | | | |
|---|---|---|---|---|---|---|---|---|
| | far- | composition of final | | | temperature | | | |
| | infrared | conductive ink | | | 150° C. | | adhesion | hardness |
| | light | | | metal | sheet | time of | test | test |
| | radiation | C₇H₁₅COOAg | xylene | powder | resistance | sintering | ASTM | ASTM |
| | (minutes) | (wt %) | (wt %) | (wt %) | (Ω/sq) | (minutes) | D3330 | D3360 |
| Example 21 | 5 | 45.5 | 45.5 | 9 | 0.58M | 5 | 1B | 6B |
| Example 22 | 10 | 45.5 | 45.5 | 9 | 0.19 | 10 | 5B | 6B |
| Example 23 | — | 45.5 | 45.5 | 9 | 12.5M | 5 | 4B | 6B |
| Example 24 | — | 45.5 | 45.5 | 9 | 0.42 | 10 | 5B | 6B |

As shown in the results of Table 6, compared with fabrication conditions with no auxiliary energy of far-infrared light of Examples 23-24, the conductive film of Example 22 coated on the PVA surface treatment layer containing the nanometer scale carbon tubes therein and formed by an auxiliary irradiated process by a far-infrared light for 10 minutes has a similar adhesion force of 5B and a low sheet resistance of 0.19 Ω/sq.

### Examples 25-28

A mixture was 0.1 wt % graphite oxide mixed with 99.9 wt % polymer system which an acrylic resin of 55 wt % was mixed with a solvent of methyl ethyl ketone (MEK) of 45 wt %. Then, the mixture was coated on a polyethylene terephthalate (PET) substrate with a thickness of 150 μm, a glass transition temperature of 80° C. and an insulating resistance of 1.82×10¹³ Ω/sq. The mixture was solidified by UV light to form a surface treatment layer having an insulating sheet resistance greater than 10¹⁴ Ω/sq.

Next, an organic acid silver (C₇H₁₅COOAg) compound of 50 wt % was dissolved in and uniformly mixed with a solvent of xylene of 50 wt % to form a metal conductive ink. Then, the metal conductive ink was coated on the surface treatment layer by a spin coating process to fabricate conductive films of the Examples 25-28. The fabrication conditions of the conductive films of the Examples 25-28 were implemented by a heat process consisting of a background temperature of 150° C. with or without an auxiliary energy of far-infrared light to sinter the metal conductive inks.

Then, the conductive films of the Examples 25-28 were measured by a cross-cut tape test of ASTM D3330, a four-point probe method and a hardness test of ASTM D3363 to obtain the adhesion forces, the sheet resistances and the hardnesses as shown in Table 7.

Table 7 displays the compositions of the metal conductive inks, the fabrication conditions, the adhesion forces, the sheet resistances and the hardnesses of the conductive films of Examples 25-28

| | time of | | | background | | | |
|---|---|---|---|---|---|---|---|
| | far- | composition of | | temperature | | | |
| | infrared | metal | | 150° C. | | adhesion | hardness |
| | light | conductive ink | | sheet | time of | test | test |
| | radiation | C₇H₁₅COOAg | xylene | resistance | sintering | ASTM | ASTM |
| | (minutes) | (wt %) | (wt %) | (Ω/sq) | (minutes) | D3330 | D3360 |
| Example 25 | 5 | 50 | 50 | 0.395M | 5 | 0B | 6B |
| Example 26 | 10 | 50 | 50 | 0.06 | 10 | 1B | 5B |
| Example 27 | — | 50 | 50 | 0.2 | 5 | 0B | 6B |
| Example 28 | — | 50 | 50 | 0.05 | 10 | 0B | 6B |

As shown in the results of Table 7, compared with fabrication conditions with no auxiliary energy of far-infrared light of Examples 27-28, the conductive film of Example 26 coated on the acrylic resin surface treatment layer containing graphite oxide therein and formed by an auxiliary irradiated process by a far-infrared light for 10 minutes has an increased adhesion force of 1B and a similar hardness of 5B.

### Examples 29-32

A mixture was 0.1 wt % graphite oxide mixed with 99.9 wt % polymer system which polyacrylic (U-Polymer) of 55 wt % was mixed with a solvent of N-methyl-2-pyrrolidone (NMP) of 45 wt %. Then, the mixture was coated on a U-Polymer substrate with a thickness of 150 μm, a glass transition temperature of 160° C. and an insulating resistance greater than 10¹⁴ Ω/sq. The mixture was solidified by UV light to form a surface treatment layer having an insulating sheet resistance of 9.95×10¹⁰ Ω/sq.

Next, an organic acid silver (C₇H₁₅COOAg) compound of 50 wt % was dissolved in and uniformly mixed with a solvent of xylene of 50 wt % to form a metal conductive ink. Then, the metal conductive ink was coated on the surface treatment layer by a spin coating process to fabricate conductive films of the Examples 29-32. The fabrication conditions of the conductive films of the Examples 29-32 were implemented by a heat process consisting of a background temperature of 150° C. with or without an auxiliary energy of far-infrared light to sinter the metal conductive inks.

Then, the conductive films of the Examples 29-32 were measured by a cross-cut tape test of ASTM D3330, a four-point probe method and a hardness test of ASTM D3363 to obtain the adhesion forces, the sheet resistances and the hardnesses as shown in Table 8.

Table 8 displays the compositions of the metal conductive inks, the fabrication conditions, the adhesion forces, the sheet resistances and the hardnesses of the conductive films of Examples 29-32

| | time of | | | background | | | |
|---|---|---|---|---|---|---|---|
| | far- | composition of | | temperature | | | |
| | infrared | metal | | 150° C. | | adhesion | hardness |
| | light | conductive ink | | sheet | time of | test | test |
| | radiation | C₇H₁₅COOAg | xylene | resistance | sintering | ASTM | ASTM |
| | (minutes) | (wt %) | (wt %) | (Ω/sq) | (minutes) | D3330 | D3360 |
| Example 29 | 5 | 50 | 50 | 0.089 | 5 | 0B | 6B |
| Example 30 | 10 | 50 | 50 | 0.027 | 10 | 0B | 6B |
| Example 31 | — | 50 | 50 | 15M | 5 | 0B | 6B |
| Example 32 | — | 50 | 50 | 0.026 | 10 | 0B | 6B |

As shown in the results of Table 8, the conductive films of Examples 29-30 formed by coating the metal conductive ink on the U-Polymer surface treatment layer containing graphite oxide therein and an auxiliary irradiating process by a far-infrared light have preferred sheet resistances and similar hardness of 6B.

### Examples 33-36

A mixture was 0.1 wt % multi-walled nanometer scale carbon tubes mixed with 99.9 wt % polymer system which an acrylic resin of 55 wt % was mixed with a solvent of methyl ethyl ketone (MEK) of 45 wt %. Then, the mixture was coated on a polycarbonate (PC) substrate with a thickness of 150 μm, a glass transition temperature of 125° C. and an insulating resistance of 1.42×10¹⁴ Ω/sq. The mixture was solidified by backing at 150° C. to form a surface treatment layer having an insulating sheet resistance of 1.02×10¹³ Ω/sq.

Next, an organic acid silver (C₇H₁₅COOAg) compound of 50 wt % was dissolved in and uniformly mixed with a solvent of xylene of 50 wt % to form a metal conductive ink. Then, the metal conductive ink was coated on the surface treatment layer by a spin coating process to fabricate conductive films of the Examples 33-36. The fabrication conditions of the conductive films of the Examples 33-36 were implemented by a heat process consisting of a background temperature of 150° C. with or without an auxiliary energy of far-infrared light to sinter the metal conductive inks.

Then, the conductive films of the Examples 33-36 were measured by a cross-cut tape test of ASTM D3330, a four-point probe method and a hardness test of ASTM D3363 to obtain the adhesion forces, the sheet resistances and the hardnesses as shown in Table 9.

### Comparative Examples 13-16

A mixture was an acrylic resin of 55 wt % mixed with methyl ethyl ketone (MEK) of 45 wt %. Then, the mixture was coated on a polycarbonate (PC) substrate with a thickness of 150 μm, a glass transition temperature of 125° C. and an insulating resistance of 1.42×10¹⁴ Ω/sq. The mixture was solidified by backing at 150° C. to form a surface treatment layer having an insulating sheet resistance greater than 1.02×10¹³ Ω/sq.

Next, an organic acid silver (C₇H₁₅COOAg) compound of 50 wt % was dissolved in and uniformly mixed with a solvent of xylene of 50 wt % to form a metal conductive ink. Then, the metal conductive ink was coated on the surface treatment layer by a spin coating process to fabricate conductive films of the Comparative Examples 13-16. The fabrication conditions of the conductive films of the Comparative Examples 13-16 were implemented by a heat process consisting of a background temperature of 150° C. with or without an auxiliary energy of far-infrared light to sinter the metal conductive inks.

Then, the conductive films of the Comparative Examples 13-16 were measured by a cross-cut tape test of ASTM D3330, a four-point probe method and a hardness test of ASTM D3363 to obtain the adhesion forces, the sheet resistances and the hardnesses as shown in Table 9.

Table 9 displays the compositions of the metal conductive inks, the fabrication conditions, the adhesion forces, the sheet resistances and the hardnesses of the conductive films of Examples 33-36 and Comparative Examples 13-16

| | time of | | | background | | | |
|---|---|---|---|---|---|---|---|
| | far- | composition of | | temperature | | | |
| | infrared | metal | | 150° C. | | adhesion | hardness |
| | light | conductive ink | | sheet | time of | test | test |
| | radiation | C₇H₁₅COOAg | xylene | resistance | sintering | ASTM | ASTM |
| | (minutes) | (wt %) | (wt %) | (Ω/sq) | (minutes) | D3330 | D3360 |
| Comparative | 5 | 50 | 50 | 191K | 5 | 0B | 6B |
| Example 13 | | | | | | | |
| Comparative | 10 | 50 | 50 | 0.03 | 10 | 0B | 6B |
| Example 14 | | | | | | | |
| Comparative | — | 50 | 50 | X | 5 | X | X |
| Example 15 | | | | | | | |
| Comparative | — | 50 | 50 | 0.0293 | 10 | 0B | 6B |
| Example 16 | | | | | | | |
| Example 33 | 5 | 50 | 50 | 0.159 | 5 | 0B | 6B |
| Example 34 | 10 | 50 | 50 | 0.0283 | 10 | 3B | 6B |
| Example 35 | — | 50 | 50 | X | 5 | X | X |
| Example 36 | — | 50 | 50 | 0.0322 | 10 | 1B | 6B |

X: non-conductive, failed in adhesion test or hardness test

As shown in the results of Table 9, the conductive films of Examples 33-34 formed by coating the metal conductive ink on the acrylic resin surface treatment layer containing multi-walled nanometer scale carbon tubes of 0.1 wt % and formed by an auxiliary irradiated process by a far-infrared light and sintering of 5 or 10 minutes have preferred sheet resistances, wherein the conductive film of Example 34 sintered of 10 minutes has a preferred adhesion force of 3B.

### Examples 37-40

A mixture was 0.1 wt % graphite oxide mixed with 99.9 wt % polymer system which an acrylic resin of 55 wt % was mixed with a solvent of methyl ethyl ketone (MEK) of 45 wt %. Then, the mixture was coated on a polycarbonate (PC) substrate with a thickness of 150 μm, a glass transition temperature of 125° C. and an insulating resistance of 1.42×10¹⁴ Ω/sq. The mixture was solidified by backing at 150° C. to form a surface treatment layer having an insulating sheet resistance of 1.02×10¹³ Ω/sq.

Next, an organic acid silver (C₇H₁₅COOAg) compound of 50 wt % was dissolved in and uniformly mixed with a solvent of xylene of 50 wt % to form a metal conductive ink. Then, the metal conductive ink was coated on the surface treatment layer by a spin coating process to fabricate conductive films of the Examples 37-40. The fabrication conditions of the conductive films of the Examples 37-40 were implemented by a heat process consisting of a background temperature of 150° C. with or without an auxiliary energy of far-infrared light to sinter the metal conductive inks.

Then, the conductive films of the Examples 37-40 were measured by a cross-cut tape test of ASTM D3330, a four-point probe method and a hardness test of ASTM D3363 to obtain the adhesion forces, the sheet resistances and the hardnesses as shown in Table 10.

Table 10 displays the compositions of the metal conductive inks, the fabrication conditions, the adhesion forces, the sheet resistances and the hardnesses of the conductive films of Examples 37-40

| | time of | | | background | | | |
|---|---|---|---|---|---|---|---|
| | far- | composition of | | temperature | | | |
| | infrared | metal | | 150° C. | | adhesion | hardness |
| | light | conductive ink | | sheet | time of | test | test |
| | radiation | C₇H₁₅COOAg | xylene | resistance | sintering | ASTM | ASTM |
| | (minutes) | (wt %) | (wt %) | (Ω/sq) | (minutes) | D3330 | D3360 |
| Example 37 | 5 | 50 | 50 | 3.3M | 5 | 0B | X |
| Example 38 | 10 | 50 | 50 | 0.035 | 10 | 0B | X |
| Example 39 | — | 50 | 50 | X | 5 | 0B | X |
| Example 40 | — | 50 | 50 | 0.066 | 10 | 0B | X |

X: non-conductive or failed in hardness test

As shown in the results of Table 10, the conductive films of Examples 37-38 formed by coating the metal conductive ink on the acrylic resin surface treatment layer containing graphite oxide of 0.1 wt % and an auxiliary irradiating process by a far-infrared light and sintering of 5 or 10 minutes have preferred sheet resistances.

### Examples 41-44

A mixture was 0.1 wt % multi-walled nanometer scale carbon tubes mixed with 99.9 wt % polymer system which polycarbonate (PC) of 55 wt % was mixed with a solvent of cyclopentanone of 45 wt %. Then, the mixture was coated on a polyethylene terephthalate (PET) substrate with a thickness of 150 μm, a glass transition temperature of 125° C. and an insulating resistance of 1.82×10¹³ Ω/sq. The mixture was solidified by backing at 150° C. to form a surface treatment layer having an insulating sheet resistance of 7.78×10¹² Ω/sq.

Next, an organic acid silver (C₇H₁₅COOAg) compound of 50 wt % was dissolved in and uniformly mixed with a solvent of xylene of 50 wt % to form a metal conductive ink. Then, the metal conductive ink was coated on the surface treatment layer by a spin coating process to fabricate conductive films of the Examples 41-44. The fabrication conditions of the conductive films of the Examples 41-44 were implemented by a heat process consisting of a background temperature of 150° C. with or without an auxiliary energy of far-infrared light to sinter the metal conductive inks.

Then, the conductive films of the Examples 41-44 were measured by a cross-cut tape test of ASTM D3330, a four-point probe method and a hardness test of ASTM D3363 to obtain the adhesion forces, the sheet resistances and the hardnesses as shown in Table 11.

### Comparative Examples 17-20

A mixture was polycarbonate (PC) of 55 wt % mixed with cyclopentanone of 45 wt %. Then, the mixture was coated on a polyethylene terephthalate (PET) substrate with a thickness of 150 μm, a glass transition temperature of 125° C. and an insulating resistance of 1.82×10¹³ Ω/sq. The mixture was solidified by backing at 150° C. to form a surface treatment layer having an insulating sheet resistance greater than 1.14×10¹⁴ Ω/sq.

Next, an organic acid silver (C₇H₁₅COOAg) compound of 50 wt % was dissolved in and uniformly mixed with a solvent of xylene of 50 wt % to form a metal conductive ink. Then, the metal conductive ink was coated on the surface treatment layer by a spin coating process to fabricate conductive films of the Comparative Examples 17-20. The fabrication conditions of the conductive films of the Comparative Examples 17-20 were implemented by a heat process consisting of a background temperature of 150° C. with or without an auxiliary energy of far-infrared light to sinter the metal conductive inks.

Then, the conductive films of the Comparative Examples 17-20 were measured by a cross-cut tape test of ASTM D3330, a four-point probe method and a hardness test of ASTM D3363 to obtain the adhesion forces, the sheet resistances and the hardnesses as shown in Table 11.

Table 11 displays the compositions of the metal conductive inks, the fabrication conditions, the adhesion forces, the sheet resistances and the hardnesses of the conductive films of Examples 41-44 and Comparative Examples 17-20

| | time of | | | background | | | |
|---|---|---|---|---|---|---|---|
| | far- | composition of | | temperature | | | |
| | infrared | metal | | 150° C. | | adhesion | hardness |
| | light | conductive ink | | sheet | time of | test | test |
| | radiation | C₇H₁₅COOAg | xylene | resistance | sintering | ASTM | ASTM |
| | (minutes) | (wt %) | (wt %) | (Ω/sq) | (minutes) | D3330 | D3360 |
| Comparative | 5 | 50 | 50 | 3.9 | 5 | 1B | 6B |
| Example 17 | | | | | | | |
| Comparative | 10 | 50 | 50 | 0.067 | 10 | 4B | B |
| Example 18 | | | | | | | |
| Comparative | — | 50 | 50 | 0.161 | 5 | 1B | HB |
| Example 19 | | | | | | | |
| Comparative | — | 50 | 50 | 0.363 | 10 | 2B | HB |
| Example 20 | | | | | | | |
| Example 41 | 5 | 50 | 50 | 0.36M | 5 | 0B | 6B |
| Example 42 | 10 | 50 | 50 | 0.106 | 10 | 5B | F |
| Example 43 | — | 50 | 50 | 0.97M | 5 | 0B | 6B |
| Example 44 | — | 50 | 50 | 1.17 | 10 | 3B | 2B |

As shown in the results of Table 11, the conductive films of Examples 41-42 formed by coating the metal conductive ink on the polycarbonate (PC) surface treatment layer containing multi-walled nanometer scale carbon tubes of 0.1 wt % and formed by an auxiliary irradiated process by a far-infrared light and sintering of 5 or 10 minutes have preferred adhesion forces and high hardnesses.

### Examples 45-48

A mixture was 0.1 wt % graphite oxide mixed with 99.9 wt % polymer system which polycarbonate (PC) of 55 wt % was mixed with a solvent of cyclopentanone of 45 wt %. Then, the mixture was coated on a polyethylene terephthalate (PET) substrate with a thickness of 150 μm, a glass transition temperature of 125° C. and an insulating resistance of 1.82×10¹³ Ω/sq. The mixture was solidified by backing at 150° C. to form a surface treatment layer having an insulating sheet resistance of 1.26×10¹⁴ Ω/sq.

Next, an organic acid silver (C₇H₁₅COOAg) compound of 50 wt % was dissolved in and uniformly mixed with a solvent of xylene of 50 wt % to form a metal conductive ink. Then, the metal conductive ink was coated on the surface treatment layer by a spin coating process to fabricate conductive films of the Examples 45-48. The fabrication conditions of the conductive films of the Examples 45-48 were implemented by a heat process consisting of a background temperature of 150° C. with or without an auxiliary energy of far-infrared light to sinter the metal conductive inks.

Then, the conductive films of the Examples 45-48 were measured by a cross-cut tape test of ASTM D3330, a four-point probe method and a hardness test of ASTM D3363 to obtain the adhesion forces, the sheet resistances and the hardnesses as shown in Table 12.

Table 12 displays the compositions of the metal conductive inks, the fabrication conditions, the adhesion forces, the sheet resistances and the hardnesses of the conductive films of Examples 45-48

| | time of | | | background | | | |
|---|---|---|---|---|---|---|---|
| | far- | composition of | | temperature | | | |
| | infrared | metal | | 150° C. | | adhesion | hardness |
| | light | conductive ink | | sheet | time of | test | test |
| | radiation | C₇H₁₅COOAg | xylene | resistance | sintering | ASTM | ASTM |
| | (minutes) | (wt %) | (wt %) | (Ω/sq) | (minutes) | D3330 | D3360 |
| Example 45 | 5 | 50 | 50 | 183K | 5 | 0B | 5B |
| Example 46 | 10 | 50 | 50 | 0.161 | 10 | 4B | 4B |
| Example 47 | — | 50 | 50 | 0.61M | 5 | 0B | 6B |
| Example 48 | — | 50 | 50 | 7.4 | 10 | 0B | 4B |

As shown in the results of Table 12, the conductive film of Example 46 formed by coating the metal conductive ink on the PC surface treatment layer containing graphite oxide of 0.1 wt % and an auxiliary irradiating process by a far-infrared light and sintering of 10 minutes has a preferred adhesion force and a preferred hardness (4B>5B>6B, wherein 4B is better than 5B and 6B).

### Examples 49-52

A mixture was 0.1 wt % clay mixed with 99.9 wt % polymer system which polycarbonate (PC) of 55 wt % was mixed with a solvent of cyclopentanone of 45 wt %. Then, the mixture was coated on a polyethylene terephthalate (PET) substrate with a thickness of 150 μm, a glass transition temperature of 125° C. and an insulating resistance of 1.82×10¹³ Ω/sq. The mixture was solidified by backing at 150° C. to form a surface treatment layer having an insulating sheet resistance of 8.39×10¹¹ Ω/sq.

Next, an organic acid silver (C₇H₁₅COOAg) compound of 50 wt % was dissolved in and uniformly mixed with a solvent of xylene of 50 wt % to form a metal conductive ink. Then, the metal conductive ink was coated on the surface treatment layer by a spin coating process to fabricate conductive films of the Examples 49-52. The fabrication conditions of the conductive films of the Examples 49-52 were implemented by a heat process consisting of a background temperature of 150° C. with or without an auxiliary energy of far-infrared light to sinter the metal conductive inks.

Then, the conductive films of the Examples 49-52 were measured by a cross-cut tape test of ASTM D3330, a four-point probe method and a hardness test of ASTM D3363 to obtain the adhesion forces, the sheet resistances and the hardnesses as shown in Table 13.

Table 13 displays the compositions of the metal conductive inks, the fabrication conditions, the adhesion forces, the sheet resistances and the hardnesses of the conductive films of Examples 49-52

| | time of | | | background | | | |
|---|---|---|---|---|---|---|---|
| | far- | composition of | | temperature | | | |
| | infrared | metal | | 150° C. | | adhesion | hardness |
| | light | conductive ink | | sheet | time of | test | test |
| | radiation | C₇H₁₅COOAg | xylene | resistance | sintering | ASTM | ASTM |
| | (minutes) | (wt %) | (wt %) | (Ω/sq) | (minutes) | D3330 | D3360 |
| Example 49 | 5 | 50 | 50 | 0.77 | 5 | 2B | 2H |
| Example 50 | 10 | 50 | 50 | 0.137 | 10 | 2B | 2H |
| Example 51 | — | 50 | 50 | 2.08M | 5 | 2B | 6B |
| Example 52 | — | 50 | 50 | 0.33 | 10 | 2B | 4B |

As shown in the results of Table 13, the conductive films of Examples 49-50 formed by coating the metal conductive ink on the PC surface treatment layer containing clay of 0.1 wt % and an auxiliary irradiating process by a far-infrared light have preferred hardnesses of 2H (H>B, wherein H is better than B).

### Examples 53-56

A mixture was 0.1 wt % multi-walled nanometer scale carbon tubes mixed with 99.9 wt % polymer system which polyacrylic (U-Polymer) of 55 wt % was mixed with a solvent of N-methyl-2-pyrrolidone (NMP) of 45 wt %. Then, the mixture was coated on a polyethylene terephthalate (PET) substrate with a thickness of 150 μm, a glass transition temperature of 125° C. and an insulating resistance of 1.82×10¹³ Ω/sq. The mixture was solidified by UV light to form a surface treatment layer having an insulating sheet resistance of 4.57×10¹³ Ω/sq.

Next, an organic acid silver (C₇H₁₅COOAg) compound of 50 wt % was dissolved in and uniformly mixed with a solvent of xylene of 50 wt % to form a metal conductive ink. Then, the metal conductive ink was coated on the surface treatment layer by a spin coating process to fabricate conductive films of the Examples 53-56. The fabrication conditions of the conductive films of the Examples 53-56 were implemented by a heat process consisting of a background temperature of 150° C. with or without an auxiliary energy of far-infrared light to sinter the metal conductive inks.

Then, the conductive films of the Examples 53-56 were measured by a cross-cut tape test of ASTM D3330, a four-point probe method and a hardness test of ASTM D3363 to obtain the adhesion forces, the sheet resistances and the hardnesses as shown in Table 14.

### Comparative Examples 21-24

A mixture was polyacrylic (U-Polymer) of 55 wt % mixed with N-methyl-2-pyrrolidone (NMP) of 45 wt %. Then, the mixture was coated on a polyethylene terephthalate (PET) substrate with a thickness of 150 μm, a glass transition temperature of 125° C. and an insulating resistance of 1.82×10¹³ Ω/sq. The mixture was solidified by UV light to form a surface treatment layer having an insulating sheet resistance of 1.42×10¹⁴ Ω/sq.

Next, an organic acid silver (C₇H₁₅COOAg) compound of 50 wt % was dissolved in and uniformly mixed with a solvent of xylene of 50 wt % to form a metal conductive ink. Then, the metal conductive ink was coated on the surface treatment layer by a spin coating process to fabricate conductive films of the Comparative Examples 21-24. The fabrication conditions of the conductive films of the Comparative Examples 24-24 were implemented by a heat process consisting of a background temperature of 150° C. with or without an auxiliary energy of far-infrared light to sinter the metal conductive inks.

Then, the conductive films of the Comparative Examples 24-24 were measured by a cross-cut tape test of ASTM D3330, a four-point probe method and a hardness test of ASTM D3363 to obtain the adhesion forces, the sheet resistances and the hardnesses as shown in Table 14.

Table 14 displays the compositions of the metal conductive inks, the fabrication conditions, the adhesion forces, the sheet resistances and the hardnesses of the conductive films of Examples 53-56 and Comparative Examples 21-24

| | time of | | | background | | | |
|---|---|---|---|---|---|---|---|
| | far- | composition of | | temperature | | | |
| | infrared | metal | | 150° C. | | adhesion | hardness |
| | light | conductive ink | | sheet | time of | test | test |
| | radiation | C₇H₁₅COOAg | xylene | resistance | sintering | ASTM | ASTM |
| | (minutes) | (wt %) | (wt %) | (Ω/sq) | (minutes) | D3330 | D3360 |
| Comparative | 5 | 50 | 50 | 0.97M | 5 | 0B | 6B |
| Example 21 | | | | | | | |
| Comparative | 10 | 50 | 50 | 0.0134 | 10 | 4B | 5B |
| Example 22 | | | | | | | |
| Comparative | — | 50 | 50 | 12.6K | 5 | 0B | 6B |
| Example 23 | | | | | | | |
| Comparative | — | 50 | 50 | 11.54K | 10 | 0B | 6B |
| Example 24 | | | | | | | |
| Example 53 | 5 | 50 | 50 | X | 5 | 1B | 6B |
| Example 54 | 10 | 50 | 50 | 0.046 | 10 | 1B | 3B |
| Example 55 | — | 50 | 50 | 8.07M | 5 | 0B | 6B |
| Example 56 | — | 50 | 50 | 4.26M | 10 | 0B | 6B |

X: non-conductive

As shown in the results of Table 14, the conductive film of Example 54 formed by coating the metal conductive ink on the U-Polymer surface treatment layer containing multi-walled nanometer scale carbon tubes of 0.1 wt % disposed on the PET substrate and formed by an auxiliary irradiated process by a far-infrared light and sintering of 10 minutes has a preferred adhesion force and a preferred hardness of 3B (3B>6B, wherein 3B is better than 6B).

### Examples 57-60

A mixture was 0.1 wt % graphite oxide mixed with 99.9 wt % polymer system which polyacrylic (U-Polymer) of 55 wt % was mixed with a solvent of N-methyl-2-pyrrolidone (NMP) of 45 wt %. Then, the mixture was coated on a polyethylene terephthalate (PET) substrate with a thickness of 150 μm, a glass transition temperature of 125° C. and an insulating resistance of 1.82×10¹³ Ω/sq. The mixture was solidified by UV light to form a surface treatment layer having an insulating sheet resistance of 1.12×10¹¹ Ω/sq.

Next, an organic acid silver (C₇H₁₅COOAg) compound of 50 wt % was dissolved in and uniformly mixed with a solvent of xylene of 50 wt % to form a metal conductive ink. Then, the metal conductive ink was coated on the surface treatment layer by a spin coating process to fabricate conductive films of the Examples 57-60. The fabrication conditions of the conductive films of the Examples 57-60 were implemented by a heat process consisting of a background temperature of 150° C. with or without an auxiliary energy of far-infrared light to sinter the metal conductive inks.

Then, the conductive films of the Examples 57-60 were measured by a cross-cut tape test of ASTM D3330, a four-point probe method and a hardness test of ASTM D3363 to obtain the adhesion forces, the sheet resistances and the hardnesses as shown in Table 15.

Table 15 displays the compositions of the metal conductive inks, the fabrication conditions, the adhesion forces, the sheet resistances and the hardnesses of the conductive films of Examples 57-60

| | time of | | | background | | | |
|---|---|---|---|---|---|---|---|
| | far- | composition of | | temperature | | | |
| | infrared | metal | | 150° C. | | adhesion | hardness |
| | light | conductive ink | | sheet | time of | test | test |
| | radiation | C₇H₁₅COOAg | xylene | resistance | sintering | ASTM | ASTM |
| | (minutes) | (wt %) | (wt %) | (Ω/sq) | (minutes) | D3330 | D3360 |
| Example 57 | 5 | 50 | 50 | 0.59 | 5 | 1B | 6B |
| Example 58 | 10 | 50 | 50 | 0.025 | 10 | 1B | 3B |
| Example 59 | — | 50 | 50 | 4.3M | 5 | 1B | 6B |
| Example 60 | — | 50 | 50 | 0.038 | 10 | 1B | 6B |

As shown in the results of Table 15, the conductive film of Example 58 formed by coating the metal conductive ink on the U-Polymer surface treatment layer containing graphite oxide of 0.1 wt % disposed on the PET substrate and an auxiliary irradiating process by a far-infrared light and sintering of 10 minutes has a preferred hardness of 3B (3B>6B, wherein 3B is better than 6B).

### Examples 61-64

A mixture of 0.1 wt % clay mixed with 99.9 wt % polyacrylic (U-Polymer) was coated on a polyethylene terephthalate (PET) substrate with a thickness of 150 μm, a glass transition temperature of 125° C. and an insulating resistance of 1.82×10¹³ Ω/sq, and then solidified by UV light to form a surface treatment layer having an insulating sheet resistance of 1.88×10¹⁴ Ω/sq.

Next, an organic acid silver (C₇H₁₅COOAg) compound of 50 wt % was dissolved in and uniformly mixed with a solvent of xylene of 50 wt % to form a metal conductive ink. Then, the metal conductive ink was coated on the surface treatment layer by a spin coating process to fabricate conductive films of the Examples 61-64. The fabrication conditions of the conductive films of the Examples 61-64 were implemented by a heat process consisting of a background temperature of 150° C. with or without an auxiliary energy of far-infrared light to sinter the metal conductive inks.

Then, the conductive films of the Examples 61-64 were measured by a cross-cut tape test of ASTM D3330, a four-point probe method and a hardness test of ASTM D3363 to obtain the adhesion forces, the sheet resistances and the hardnesses as shown in Table 16.

Table 16 displays the compositions of the metal conductive inks, the fabrication conditions, the adhesion forces, the sheet resistances and the hardnesses of the conductive films of Examples 61-64

| | time of | | | background | | | |
|---|---|---|---|---|---|---|---|
| | far- | composition of | | temperature | | | |
| | infrared | metal | | 150° C. | | adhesion | hardness |
| | light | conductive ink | | sheet | time of | test | test |
| | radiation | C₇H₁₅COOAg | xylene | resistance | sintering | ASTM | ASTM |
| | (minutes) | (wt %) | (wt %) | (Ω/sq) | (minutes) | D3330 | D3360 |
| Example 61 | 5 | 50 | 50 | X | 5 | 0B | 6B |
| Example 62 | 10 | 50 | 50 | 0.055 | 10 | 2B | 6B |
| Example 63 | — | 50 | 50 | 9M | 5 | 1B | 6B |
| Example 64 | — | 50 | 50 | 0.71 | 10 | 3B | 6B |

X: non-conductive

As shown in the results of Table 16, the conductive film of Example 62 formed by coating the metal conductive ink on the U-Polymer surface treatment layer containing clay of 0.1 wt % disposed on the PET substrate and an auxiliary irradiating process by a far-infrared light and sintering of 10 minutes has a preferred sheet resistance.

In summary, the substrate assemblies according to the embodiments of the invention utilize the surface treatment layer disposed between the polymer substrate and the conductive film to enhance the adhesion force between the conductive film and the polymer substrate and utilize the auxiliary filler in the surface treatment layer to deliver an energy to the metal conductive ink for auxiliary sintering of the metal conductive ink to form the conductive film at a low fabrication process temperature and a short sintering time. Therefore, compared with conventional methods of adding a polymer to a conductive ink to enhance the adhesion force of a conductive film, the conductive films of the substrate assemblies according to the embodiments of the invention have a thinner thickness and a better electrically conductive property. Moreover, the surface treatment layers of the substrate assemblies according to the embodiments of the invention are suitable for flexible substrates and satisfy application requirements for flexible electronic products.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A substrate assembly, comprising:
a polymer substrate;
a surface treatment layer disposed on the polymer substrate; and
a conductive film disposed on the surface treatment layer,
wherein the surface treatment layer is a composite material of an auxiliary filler and a polymer, the conductive film is formed by sintering a metal conductive ink, and the auxiliary filler in the surface treatment layer has an energy delivering ability for delivering an energy to the metal conductive ink for sintering the metal conductive ink.

2. The substrate assembly as claimed in claim 1, wherein the material of the polymer substrate comprises a thermoplastic polymer, a thermosetting polymer or a combination thereof, and the polymer substrate has an insulating resistance between 10¹⁴ Ω/sq and 10¹⁶ Ω/sq and a glass transition temperature between 80° C. and 160° C.

3. The substrate assembly as claimed in claim 2, wherein the material of the polymer substrate comprises polyester, polyacrylic, polycarbonate (PC), epoxy resin or polyurethane (PU), and wherein the polyester comprises polyethylene terephthalate (PET).

4. The substrate assembly as claimed in claim 1, wherein the auxiliary filler in the surface treatment layer is 0.01 to 5 percent by weight and the auxiliary filler is selected from the group consisting of a nanometer scale tube, a nanometer scale sphere, a carbon containing material and a clay.

5. The substrate assembly as claimed in claim 4, wherein the nanometer scale tube comprises a single-walled nanometer scale carbon tube, a multi-walled nanometer scale carbon tube or a combination thereof, the nanometer scale sphere comprises a nanometer scale carbon sphere, the carbon containing material comprises graphite or graphite oxide, and the clay is selected from the group consisting of clay composites of oxides of the elements in Group IA, Group IIA and Group IVA of the periodic table.

6. The substrate assembly as claimed in claim 1, wherein the polymer of the surface treatment layer comprises a thermoplastic polymer, a thermosetting polymer or a combination thereof.

7. The substrate assembly as claimed in claim 1, wherein the polymer of the surface treatment layer has a glass transition temperature between 75° C. and 200° C.

8. The substrate assembly as claimed in claim 7, wherein the polymer is selected from the group consisting of acrylic resin, polyacrylic (U-Polymer), polyvinyl alcohol (PVA) and polycarbonate (PC).

9. The substrate assembly as claimed in claim 1, wherein a composition of the metal conductive ink comprises a metallo-organic compound and a solvent, or a metallo-organic compound, a metal powder and a solvent, and the metallo-organic compound is 25 to 60 percent by weight of the metal conductive ink.

10. The substrate assembly as claimed in claim 9, wherein the metallo-organic compound is represented by (RCOO)_{y}M^{(y)}, and wherein R is a straight-chain or a branched-chain CₙH₂ₙ₊₁, n is an integral of 5-20, M is metal, selected from the group consisting of copper, silver, gold, aluminum, titanium, nickel, tin, platinum and palladium, and y is a valence of the metal.

11. The substrate assembly as claimed in claim 9, wherein the size of the metal powder is smaller than 500 nm, the material of the metal powder is selected from the group consisting of copper, silver, gold, aluminum, titanium, nickel, tin, platinum and palladium, and the solvent is selected from the group consisting of xylene, toluene and terpenol.

12. A method for fabricating a substrate assembly, comprising:
providing a polymer substrate;
coating a mixture of an auxiliary filler and a polymer on the polymer substrate;
solidifying the mixture of the auxiliary filler and the polymer to form a surface treatment layer;
coating a metal conductive ink on the surface treatment layer; and
applying a first energy source and an second energy source to the polymer substrate, the surface treatment layer and the metal conductive ink for sintering the metal conductive ink to form a conductive film,
wherein the auxiliary filler in the surface treatment layer has an energy delivering ability for delivering the energies of the first energy source and an second energy source to the metal conductive ink.

13. The method as claimed in claim 12, wherein the first energy source and the auxiliary second energy source are selected from the group consisting of heat, light, energy waves and laser, the first energy source is different from the second energy source, and the first energy source has a temperature range between 90° C. and 150° C.

14. The method as claimed in claim 13, wherein the light with energy is selected from the group consisting of an ultraviolet light, a near-infrared light, a middle-infrared light and a far-infrared light, and the energy waves comprises a microwave with a wavelength of 300 MHz-300 GHz, and the laser is selected from the group consisting of a gaseous laser, a solid-state laser and a liquid laser.

15. The method as claimed in claim 12, wherein the steps of coating the mixture of the auxiliary filler and the polymer and the metal conductive ink comprise a wet coating process.
